(19) United States
(12) Patent Application Publication
(10) Pub. No.: US 2025/0260387 A1
(43) Pub. Date: Aug. 14, 2025

(54) ACOUSTIC FILTER ASSEMBLY WITH TUNABLE PASSBAND, A RADIO FREQUENCY MODULE, AND MOBILE DEVICE INCLUDING THE SAME

(71) Applicant: SKYWORKS SOLUTIONS, INC., Irvine, CA (US)

(72) Inventors: Grant Darcy Poulin, Carp (CA); Olzhas Tazabekov, Toronto (CA)

(21) Appl. No.: 19/036,144

(22) Filed: Jan. 24, 2025

Related U.S. Application Data
(60) Provisional application No. 63/551,762, filed on Feb. 9, 2024.

(51) Int. Cl. H03H 9/54; H04B 1/12; H04B 1/3827

(52) U.S. Cl. CPC H03H 9/545; H04B 1/123; H04B 1/3827

(57) ABSTRACT

An acoustic filter assembly for operating at a first band adjacent to a second band without a spacing between the first band and the second band is presented, including a band-pass filter configured have a transition band between the passband and a stopband; and an interface configured to receive a control signal that controls a width of the pass band such that the transition band is shifted in frequency, the control signal adjusting a location of the transition band between a first position and a second position, one end of the transition band near to the stopband being aligned with a boundary between the first band and the second band in the first position, the other end of the transition band near to the pass band being aligned with the boundary between the first band and the second band in the second position.

### CROSS-REFERENCE TO RELATED APPLICATIONS

This application claims priority under 35 U.S.C. § 119 (e) to U.S. Provisional Patent Application 63/551,762 titled AN ACOUSTIC FILTER ASSEMBLY WITH TUNABLE PASSBAND, A RADIO FREQUENCY MODULE, AND MOBILE DEVICE INCLUDING THE SAME, filed on Feb. 9, 2024, and hereby incorporated by reference in its entirety for all purposes.

### BACKGROUND

### Field

Embodiments of the present disclosure relate to electronic systems, and in particular, to acoustic filter assemblies for use in radio frequency (RF) electronics.

### Description of the Related Technology

Radio frequency (RF) is a common term for a range of frequency of electromagnetic radiation typically used to produce and detect radio waves. Such a range can be from about 30 kHz to 300 GHz. Wireless communication devices often include front-end circuitry for processing or conditioning RF signals at an incoming or outgoing frequency or signal port. RF front-end modules may be components of receiver, transmitter, or transceiver systems associated with a wireless device.

RF front-end design may include a number of considerations, including complexity, substrate compatibility, performance, and integration. It can be desirable for wireless devices to support multiple wireless technologies. For instance, modern mobile phones and other wireless devices send and receive growing quantities of electronic data including email, electronic documents, data communicated during web browsing sessions, and the like, often by incorporating a wide area network (WLAN) interface. Modern devices often also support wireless connection to other electronic devices that are local to the user, including wireless headsets, ear-pieces, watches, and other so called “wearable” devices. For instance, some wireless devices support Bluetooth communication, and can connect to Bluetooth capable wearable devices, or other Bluetooth capable devices in proximity to the wireless device.

### BRIEF DESCRIPTION OF THE DRAWINGS

FIG. 1 is a schematic block diagram of an example of a wireless device.

FIG. 2, which includes FIGS. 2A, 2B, and 2C shows an allocation of an unlicensed band and a licensed band.

FIG. 3 is an example of schematic diagram of access point (AP) according to an embodiment of the present disclosure.

FIG. 4, which includes FIGS. 4A, 4B, and 4C shows an example of a location of the transition band in the first position.

FIG. 5, which includes FIGS. 5A, 5B, and 5C shows an example of a location of the transition band in the second position.

FIG. 6A is a filter circuit according to an example.

FIG. 6B is a graph of various modes of operation according to an example.

FIG. 6C is a graph of various modes of operation according to an example.

FIG. 7A is a schematic diagram of one embodiment of a packaged module.

FIG. 7B is a schematic diagram of a cross-section of the packaged module of FIG. 6A taken along the lines 6B-6B.

FIG. 8 is a schematic diagram of one embodiment of a phone board.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

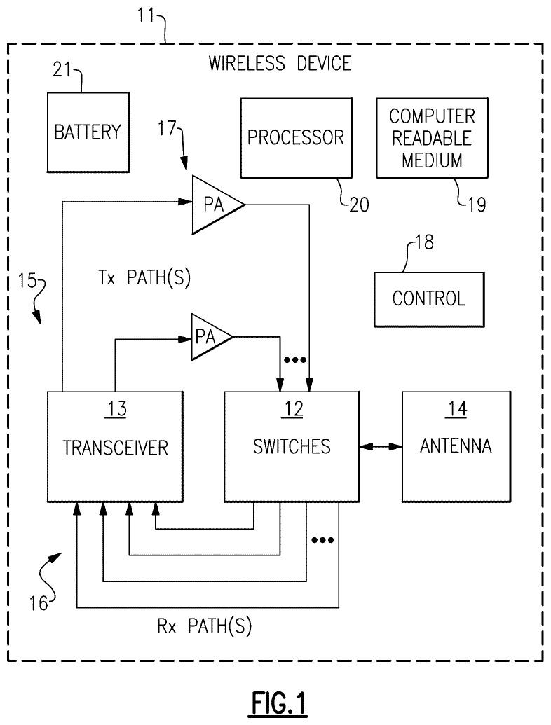

FIG. 1 is a schematic block diagram of an example of a wireless device 11. The wireless device 11 can include a power amplifier bias circuit implementing one or more features of the present disclosure in a control component 18. The power amplifier bias circuit can include a control circuit and a primary biasing circuit.

The example wireless device 11 depicted in FIG. 1 can represent a multi-band and/or multi-mode device such as a multi-band/multi-mode mobile phone. In certain embodiments, the wireless device 11 can include a switch module 12, a transceiver 13, an antenna 14 (or multiple antennas), power amplifiers 17, a control component 18, a computer readable medium 19, a processor 20, and a battery 21.

The transceiver 13 can generate RF signals for transmission via the antenna 14. Furthermore, the transceiver 13 can receive incoming RF signals from the antenna 14.

It will be understood that various functionalities associated with the transmission and receiving of RF signals can be achieved by one or more components that are collectively represented in FIG. 1 as the transceiver 13. For example, a single component can be configured to provide both transmitting and receiving functionalities. In another example, transmitting and receiving functionalities can be provided by separate components.

Similarly, it will be understood that various antenna functionalities associated with the transmission and receiving of RF signals can be achieved by one or more components that are collectively represented in FIG. 1 as the antenna 14. For example, a single antenna can be configured to provide both transmitting and receiving functionalities. In another example, transmitting and receiving functionalities can be provided by separate antennas. In yet another example, different bands associated with the wireless device 11 can be provided with different antennas.

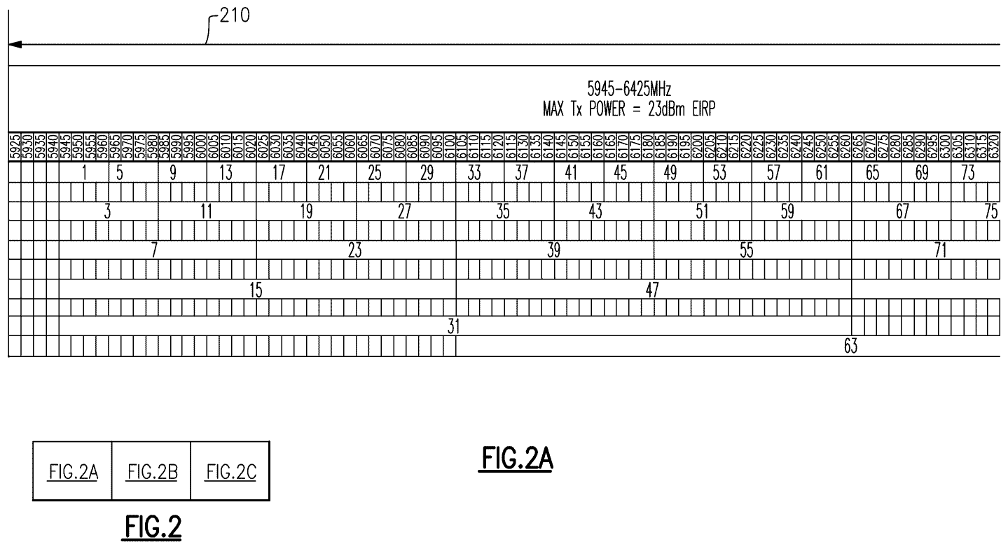

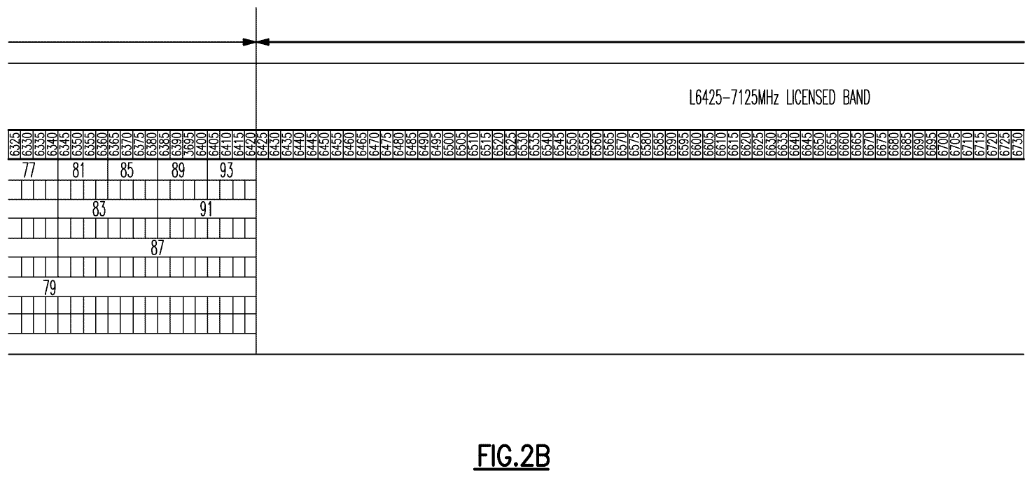

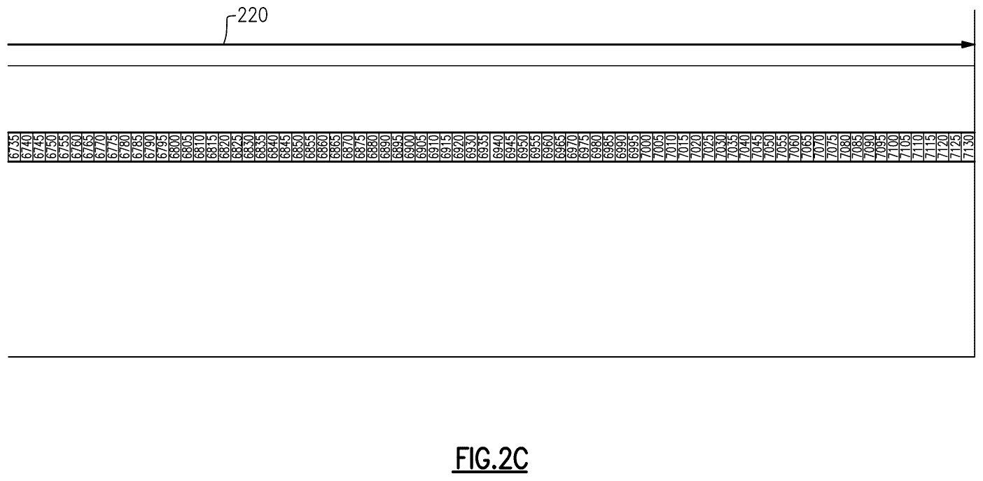

In FIG. 1, one or more output signals from the transceiver 13 are depicted as being provided to the antenna 14 via one or more transmission paths 15. In the example shown, different transmission paths 15 can represent output paths associated with different bands and/or different power outputs. For instance, the two example power amplifiers 17 shown can represent amplifications associated with different power output configurations (e.g., low power output and high power output), and/or amplifications associated with different bands. Although FIG. 2 illustrates a configuration using two transmission paths 15, the wireless device 11 can include more or fewer transmission paths 15.

The power amplifiers 17 can be used to amplify a wide variety of RF signals. For example, one or more of the power amplifiers 17 can receive an enable signal that can be used to pulse the output of the power amplifier to aid in transmitting a wireless local area network (WLAN) signal, such as a WLAN 802.11be signal, or any other suitable pulsed signal. In certain embodiments, one or more of the power amplifiers 17 are configured to amplify a Wi-Fi signal. Each of the power amplifiers 17 need not amplify the same type of signal. For example, one power amplifier can amplify a WLAN signal, while another power amplifier can amplify, for example, another WLAN signal, a Global System for Mobile (GSM) signal, a code division multiple access (CDMA) signal, a W-CDMA signal, a Long Term Evolution (LTE) signal, or a 5G signal.

One or more features of the present disclosure can be implemented in the foregoing example communication standards, modes and/or bands, and in other communication standards.

In FIG. 1, one or more detected signals from the antenna 14 are depicted as being provided to the transceiver 13 via one or more receiving paths 16. In the example shown, different receiving paths 16 can represent paths associated with different bands. Although FIG. 1 illustrates a configuration using four receiving paths 16, the wireless device 11 can be adapted to include more or fewer receiving paths 16.

To facilitate switching between receive and transmit paths, the switch module 12 can be configured to electrically connect the antenna 14 to a selected transmit or receive path. Thus, the switch module 12 can provide a number of switching functionalities associated with an operation of the wireless device 11. In certain embodiments, the switch module 12 can include a number of switches configured to provide functionalities associated with, for example, switching between different bands, switching between different power modes, switching between transmission and receiving modes, or some combination thereof. The switch module 12 can also be configured to provide additional functionality, including filtering and/or duplexing of signals.

FIG. 1 shows that in certain embodiments, a control component 18 can be provided for controlling various control functionalities associated with operations of the switch module 12, the power amplifiers 17, and/or other operating component(s). The control component 18 can be implemented on the same die as the power amplifier 17 in certain implementations. The control component 18 can be implemented on a different die than the power amplifier 17 in some implementations. Non-limiting examples of the control component 18 that include a control circuit and a bias circuit to achieve a desired balance of Error Vector Magnitude (EVM) reduction and Out of Band (OOB) emissions are described herein in greater detail.

In certain embodiments, a processor 20 can be configured to facilitate implementation of various processes described herein. For the purpose of description, embodiments of the present disclosure may also be described with reference to flowchart illustrations and/or block diagrams of methods, apparatus (systems) and computer program products. It will be understood that each block of the flowchart illustrations and/or block diagrams, and combinations of blocks in the flowchart illustrations and/or block diagrams, may be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the acts specified in the flowchart and/or block diagram block or blocks.

In certain embodiments, these computer program instructions may also be stored in a computer-readable memory 19 that can direct a computer or other programmable data processing apparatus to operate in a particular manner, such that the instructions stored in the computer-readable memory produce an article of manufacture including instruction means which implement the acts specified in the flowchart and/or block diagram block or blocks. The computer program instructions may also be loaded onto a computer or other programmable data processing apparatus to cause a series of operations to be performed on the computer or other programmable apparatus to produce a computer implemented process such that the instructions that execute on the computer or other programmable apparatus provide instructions for implementing the acts specified in the flowchart and/or block diagram block or blocks.

The battery 21 can be any suitable battery for use in the wireless device 11, including, for example, a lithium-ion battery. Some configurations will not use a battery and will instead use a DC-DC converter to supply the power to the wireless device.

FIG. 2 shows an allocation of an unlicensed band and a licensed band. Recently, the European Union (EU) has approved operation in the 6 GHz band from 5925 MHz to 6425 MHz for unlicensed operation, and this is typically used for Wi-Fi devices. Final rules for spectrum above 6425 MHz have not yet been completed, but it is expected that this spectrum will be allocated for licensed use in the EU. In the United States (US) of America, the entire spectrum from 5945 MHz to 7125 MHz is currently allocated for unlicensed use.

If a certain country allows unlicensed operation (Wi-Fi) in the 5925 MHz to 6425 MHz band and allows licensed devices to operate in the 6425 MHz to 7125 MHz band, devices operating in the two bands will need to coexist. Wi-Fi devices will operate from 5925 MHz to 6425 MHz, and licensed cellular devices will operate from 6425 MHz to 7125 MHz. In order to co-exist, filtering will be required, especially if a Wi-Fi and cellular radio are in the same device, i.e., a customer premise equipment (CPE) using two co-located radios: a cellular radio to connect to a wide area network (WAN) for internet access, and a Wi-Fi radio to create a local area network (LAN) inside a home. Any filtering in the 5925 MHz to 6425 MHz band will need a transition band where the filter transitions from passband to stopband. Typically, the transition band will be about 100 MHz wide, and the use of any channels that are inside the transition band will not be possible. The exact location of the transition band will determine how much spectrum is available for Wi-Fi, and how much spectrum is available for licensed use.

In this disclosure, it is proposed to efficiently shift the transition band so as to flexibly use the spectrum depending on required amount of traffic on the corresponding bands.

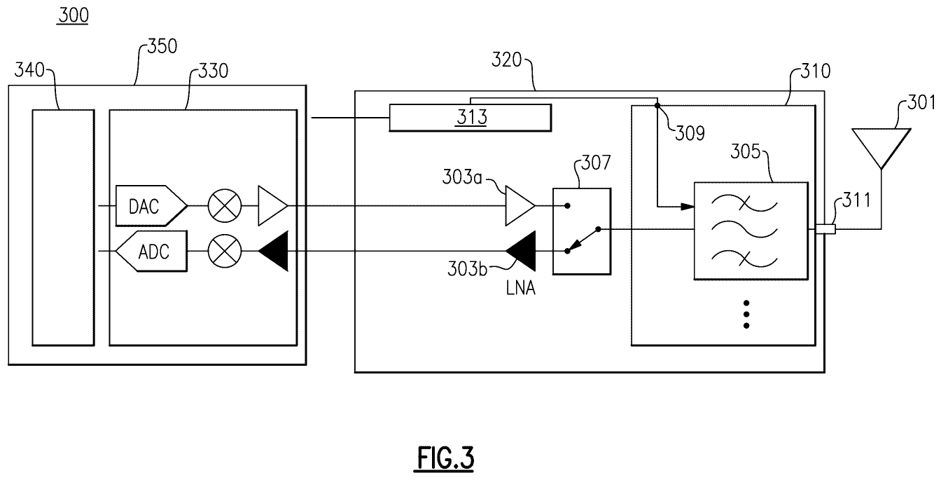

FIG. 3 is an exemplary schematic diagram of an access point (AP) according to an embodiment of the present disclosure. As shown in FIG. 3, the AP 300 may include a filter assembly 310. In this description, the AP 300 may be also referred to as a wireless device. The filter assembly 310 may be provided to operate at a first band adjacent to a second band. The first band may be an unlicensed band, and the second band may be a licensed band. Thus, the filter assembly 300 may be configured to operate on the unlicensed band. The first band may have a lower frequency range than the second band. That is, the first band may be located below the second band. The first band and the second band may be arranged so that no spacing exists between the first band and the second band. For example, the first band may be located in the range from 5945 MHz to 6425 MHz and the second band may be located in the range from 6425 MHz to 7125 MHz. In this case, the boundary between the first band and the second band may be located at 6425 MHz.

The filter assembly 310 may include a band-pass filter 305. Although one band-pass filter 305 is shown in FIG. 3, more than one band-pass filter 305 may be included in the filter assembly 310. The band-pass filter 305 may be BAW filter. The band-pass filter 305 may be configured to allow signals received via an antenna node 311 to pass at a pass band of the band-pass filter 305. The pass band according to an embodiment may cover at least a part of 6 GHz frequency region, for example it may cover the range from 5945 MHz to 6425 MHz.

The band-pass filter 305 may be configured to have a transition band outside the passband. More specifically, the transition band may be located between the pass band and a stop band. The stop band may be a frequency range where the signals are completely filtered out by the band-pass filter 305. The transition band may be a frequency range where some of the signals are unintentionally partially allowed, and therefore operation in the range of the transition band is not possible. According to an embodiment, the transition band may have a width of 100 MHz.

The antenna node 311 may be connected to the antenna 301. The signals may be received by the antenna 301 and delivered to the filter assembly 310 via the antenna node 311.

The filter assembly 310 may further include the interface 309 configured to receive a control signal that is configured to control a width of the pass band such that the transition band is shifted in frequency. According to an embodiment, one end of the transition band may be fixed and the other end of the transition band may be flexibly adjusted by the control signal. In this embodiment, a location of the transition band located on the side of adjustable end may be shifted. For example, the lower end of the filter may be fixed at 5945 MHZ, and the upper end may be flexibly adjusted between 6325 MHz and 6425 MHz.

The control signal may be configured to adjust a location of the transition band between a first position and a second position. More specifically, the location of the transition band may be located somewhere between the first position and the second position. In the first position, one end of the transition band near to the stopband may be aligned with a boundary between the first band and the second band. In the second position, the other end of the transition band near to the pass band may be aligned with the boundary between the first band and the second band. In both the first position and the second position, the width of the transition band may be maintained identical. In other words, the transition band may have a substantially same width in both the first position and the second position.

According to an embodiment of the present disclosure, since the location of the transition band can be flexibly adjusted, there is no need to waste effort to reduce the width of the transition band and therefore more efficient operation can be achieved.

The control signal may be configured to adjust the location of the transition band between the first position and the second position depending on a required amount of spectrum of the first band.

According to an embodiment of the present disclosure, the band-pass filter 305 may include at least one resonator, which is selectively connected with a reactive element by the control signal to adjust a resonance frequency or an anti-resonance frequency of the resonator. The reactive element may be an inductor and/or a capacitor. For example, the resonator may be connected in series with the inductor and connected in parallel with the capacitor. The inductor may be further connected in parallel with a switch and the capacitor may be further connected in series with another switch, with a combination of the other switch and the capacitor being connected parallel with the resonator. By controlling each of the switches (e.g., to place the inductor in series with the resonator (or not) and/or to place the capacitor in parallel with the resonator (or not)), the resonance frequency and the anti-resonance frequency of the resonator can be adjusted. However, the implementation of shifting the transition band is not limited thereto. Any techniques that enable one to adjust the width of the pass band can be used. For example, the method for controlling the rolloff stiffness of a notch filter can be used.

In one example, an RF cancellation technique can be also used for shifting the transition band. More specifically, the RF cancellation may include sampling the desired signal, adjusting its amplitude, inverting its phase, and then adding it back to the original signal.

According to an embodiment of the present disclosure, the AP 300 may further include a front-end module 320. The front-end module 320 may include the filter assembly 310 described above. The front-end module 320 may be configured to generate the control signal to be provided to the filter assembly 305. These control signals can be sent over the interface 309, for example a digital interface, using dedicated GPIOs, over a SPI or I2C serial bus, or over a MIPI interface if so equipped.

The front-end module 320 may include a controller 313 configured to generate the control signal. The controller 313 may receive a signal from a SoC (system on chip) 350. More specifically, the filter tuning can be controlled by SoC 350, which comprises an OFDM generator 340 and an RF transceiver 330. The SoC 350 may be capable of knowing exactly what channels are being used and it will eventually send control signals to the filter to properly configure them.

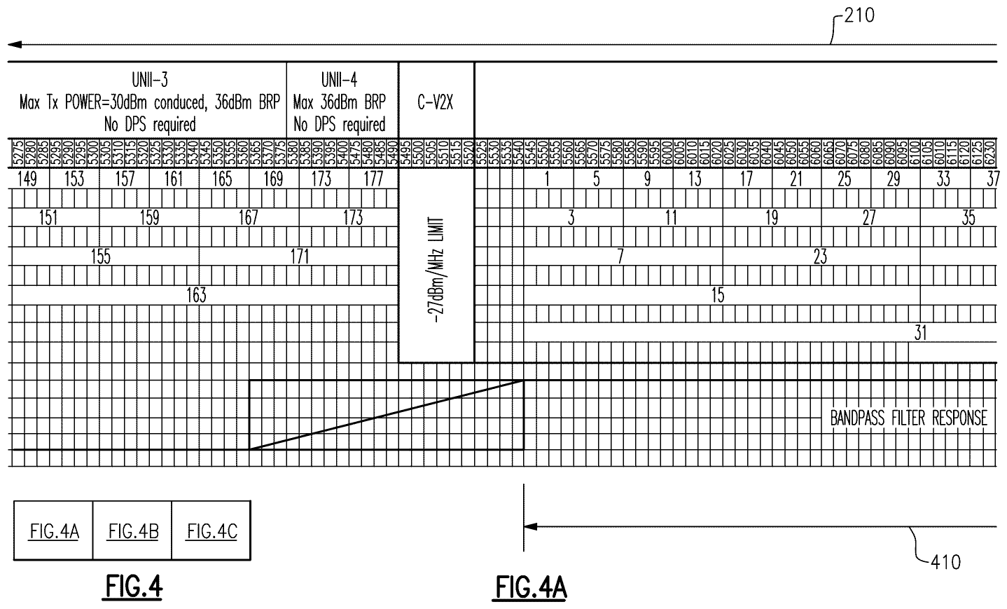

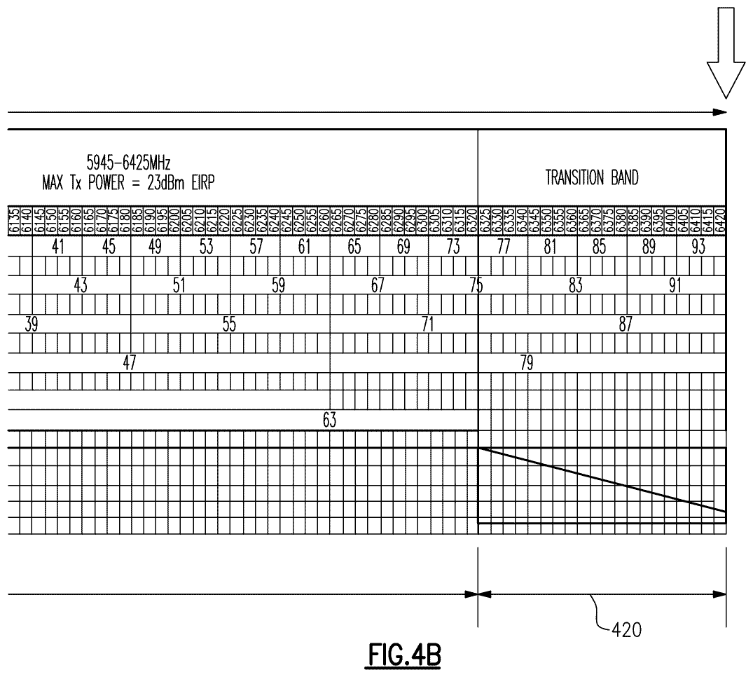

FIG. 4 shows an example of a location of the transition band in the first position. As shown in FIG. 4, in the first position, one end of the transition band 420 near to the stopband 430 may be aligned with a boundary between the first band 210 and the second band 220. In this case, the upper part of the first band 210 may not be used. In turn, the 5 GHz band (UNII-3) that falls within the lower part of the pass band 410 may be available and thus it allows for 5GHz simultaneous operation. Thus, the control signal may locate the transition band in the first position when the required amount of traffic in the first band 210 is not maximum, or when there are users in the licensed band 220 that require the use of spectrum at 6425 MHz. As described above, the other opposite side of the pass band 410 may be fixed. Note that in this configuration, some of the Wi-Fi channels in the unlicensed band between 6325 MHz and 6425 MHz will be not be available for Wi-Fi use, as they are in the transition band,

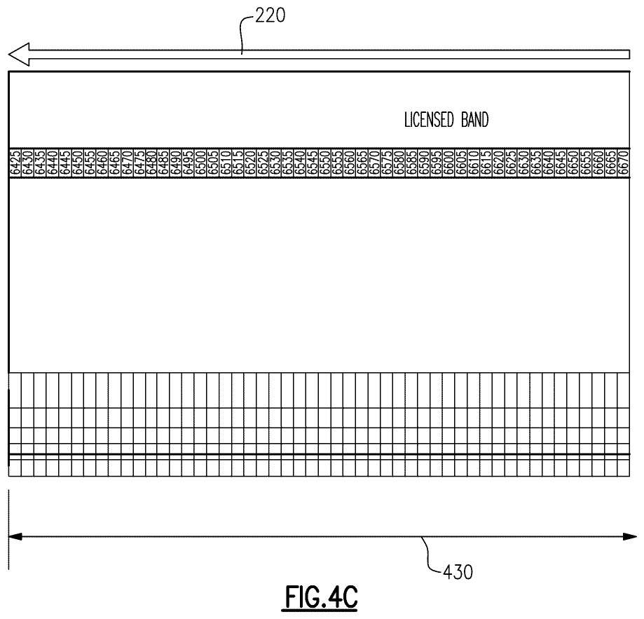

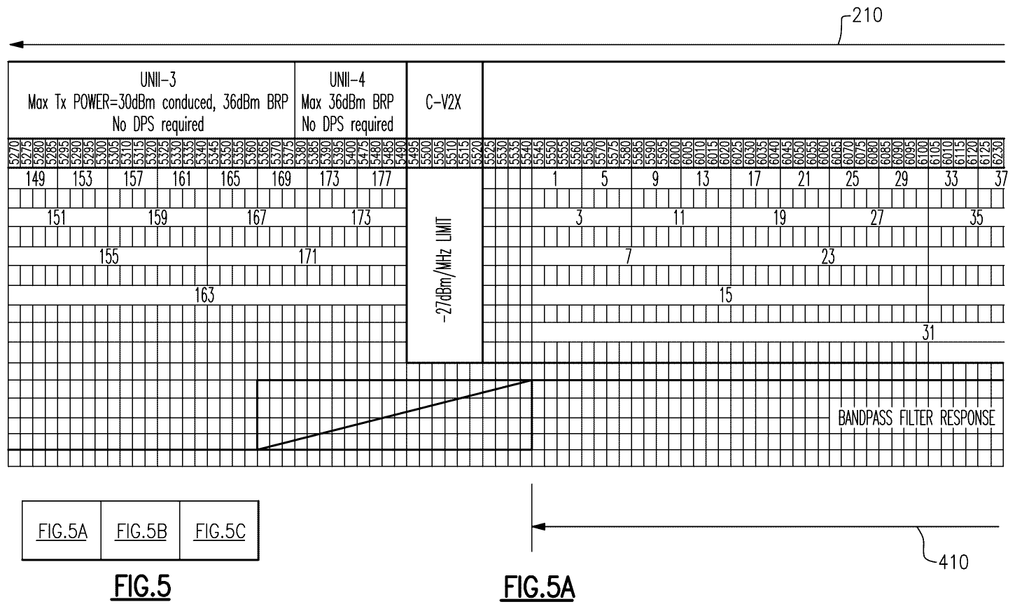

FIG. 5 shows an example of a location of the transition band in the second position. In the second position, the other end of the transition band 420 near to the pass band 410 may be aligned with the boundary between the first band 210 and the second band 220. In this case, the lower part of the second band 220 may not be used but the entire Wi-Fi band in the unlicensed band from 5945 MHz to 6425 MHz may be used. Thus, the control signal may locate the transition band in the second position when the required amount of traffic in the first band 210 is maximum, or when there is no need to support users in the licensed band 220 between 6425 MHz and 6525 MHz. As described above, the other opposite side of the pass band 410 may be fixed.

According to the present disclosure, it is not necessary to reduce the transition band when the transition band is switched between the first and second position, and therefore the self-interference can be prevented using practical BAW filters with non-zero transition width.

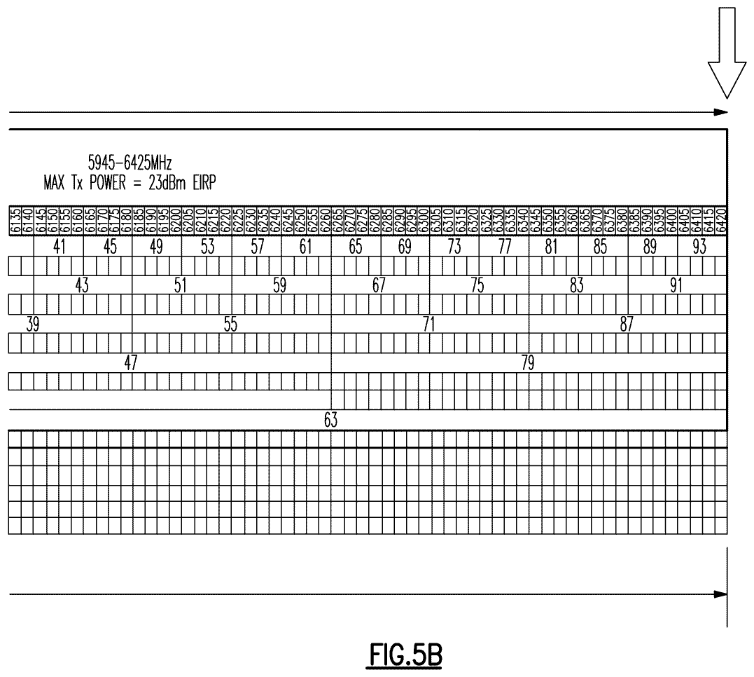

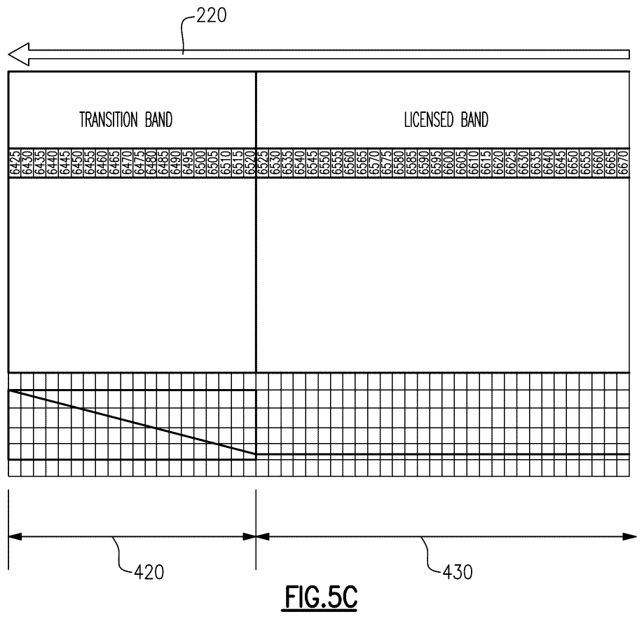

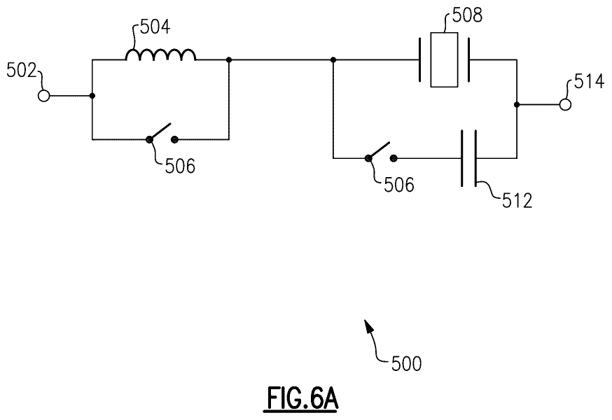

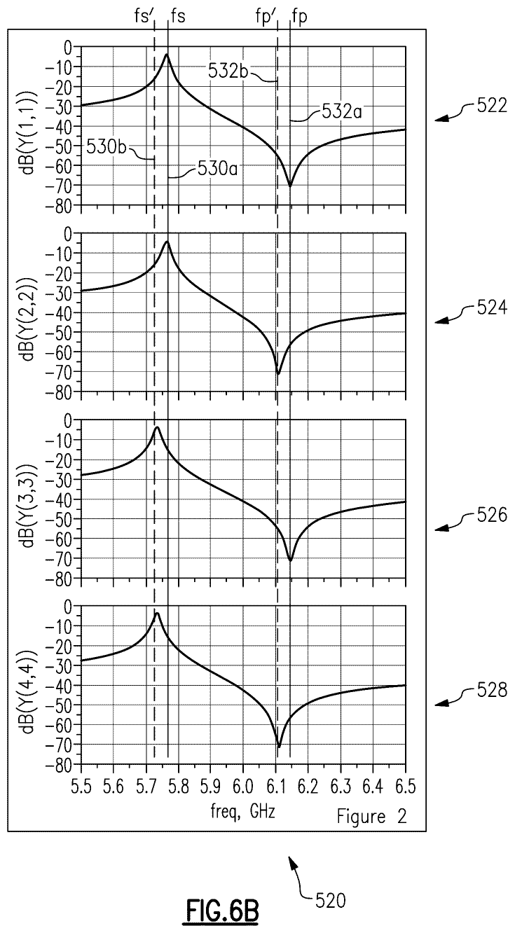

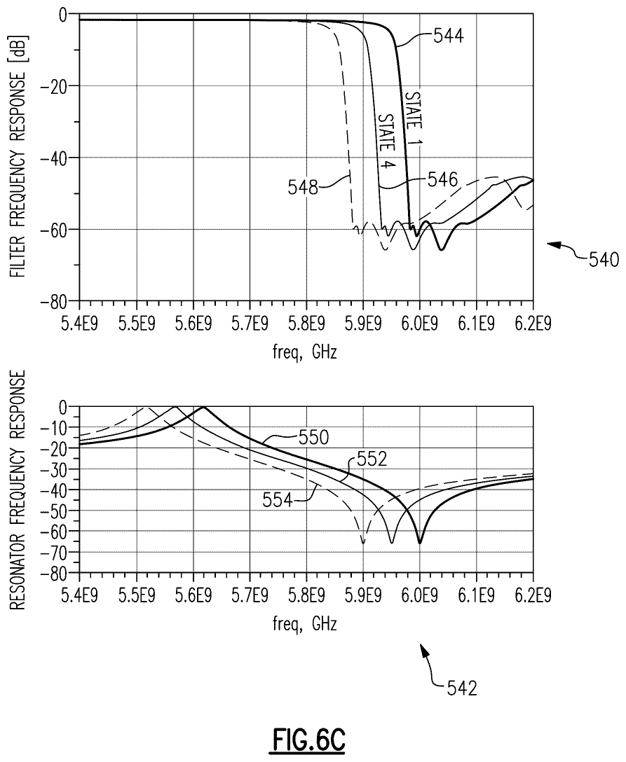

FIG. 6A illustrates a schematic diagram of a circuit 500 according to an example. The circuit 500 includes a first node 502, an inductor 504, a first switch 506, a resonator 508, a second switch 510, a capacitor 512, and a second node 514.

The first node 502 is coupled to a first connection of the inductor 504 and to a first connection of the first switch 506. A second connection of the inductor 504 and a second connection of the first switch 506 are coupled to a first connection of the resonator 508 and a first connection of the second switch 510. A second connection of the second switch 510 is coupled to a first connection of the capacitor 512. A second connection of the resonator 508 and a second connection of the capacitor 512 are coupled to the second node 514.

The circuit 500 may have one or more resonance frequencies and one or more antiresonance frequencies. In some examples, the resonance and antiresonance frequencies may correspond to resonances of the resonator 508.

In a first mode of operation, the first switch 506 may be closed (thereby bypassing the inductor 504) and the second switch 510 may be open (thereby disconnecting the capacitor 512). As a result, the inductor 504 and capacitor 512 will not contribute to the resonance of the circuit 500. Accordingly, the resonance and antiresonance of the circuit 500 may depend entirely and/or primarily upon the resonator 508, and may be impacted minimally or not at all by the inductor 504 and capacitor 512. For the purposes of discussion, the resonance frequency in the first mode shall be referred to as “fs” and the antiresonance frequency in the first mode shall be referred to as “fp” in the following discussion of FIG. 6A.

In a second mode of operation, the first switch 506 may be closed and the second switch 510 may be closed. As a result, the resonance and antiresonance frequencies of the circuit 500 may be affected by the capacitor 512 but not the inductor 504. As a result, the resonance frequency may remain at a value of fs as the resonance frequency may continue to depend on the resonance of the resonator 508, while the antiresonance frequency may be a new value, “fp′”, based on the parallel combination of the resonator 508 and the capacitor 512. In some examples, fp′ will be a lower frequency than fp (though fp′ can also be made to be higher than fp).

In a third mode of operation, the first switch 506 may be open (connecting the inductor 504 to the circuit 500) and the second switch 510 may be open (disconnecting the capacitor 512). Thus, the antiresonance frequency may remain at the value of fp (e.g., the value in the first mode of operation), while the resonance frequency may shift to “fs′”, as it now depends on the series combination of the inductor 504 and the resonator 508. In some examples, fs′ may be a lower frequency than fs (though fs′ can also be made to be higher than fs).

In a fourth mode of operation, the first switch 506 is open and the second switch 510 is closed, so that both inductor 504 and capacitor 512 impact the respective resonance and antiresonance frequencies of the circuit 500. In particular, the resonance frequency may be fs′ and the antiresonance frequency may be fp′.

FIG. 6B illustrates a graph 520 illustrating changes in the resonance and antiresonance frequencies according to an example.

Each graph illustrates an example of a response function of the circuit 500 or a similar circuit. A first resonant frequency trace 530a, a second resonant frequency trace 530b, a first antiresonance frequency trace 532a, and a second antiresonance frequency trace 532b pass through each graph 522, 524, 526, 528, indicating how the peak or minimum of the response function illustrated in each graph corresponds to fs, fs′, fp, and/or fp′.

The first graph 522 illustrates the response function corresponding to the first mode of operation, where the peak of the response function corresponding to the resonance frequency of the circuit is equal to fs, and the minimum of the resonance frequency is equal to fp.

The second graph 524 illustrates the response function corresponding to the second mode of operation, where the peak of the response function occurs at a frequency of fs and the minimum of the response function occurs at a frequency of fp′

The third graph 526 illustrates the response function corresponding to the third mode of operation, where the peak of the response function occurs at a frequency of fs′ and the minimum of the response function occurs at a frequency of fp.

The fourth graph 528 illustrates the response function corresponding to the fourth mode of operation, where the peak of the response function occurs at a frequency of fs′ and the minimum of the response function occurs at a frequency of fp′.

FIG. 6C illustrates a pair of related graphs, including a first graph 540 and a second graph 542, according to an example. The first graph 540 illustrates response functions of a filter according to an example. The second graph 542 illustrates response functions of a resonator according to an example. In some examples, the resonator may be a resonator in the filter.

In the first graph 540, there is a first trace 544, a second trace 546, and a third trace 548. The first trace 544 illustrates the response of the filter when the circuit 500 of FIG. 6A (or an equivalent circuit) is in the first mode of operation, and the second trace 546 illustrates the response of the filter when the circuit 500 (or equivalent) is in the fourth mode of operation. The third trace 548 represents the response of the filter if the circuit 500 and/or filter is provided with additional tuning (e.g., additional capacitors and/or inductors) switched in (e.g., affecting the response of the circuit 500).

The second graph 542 illustrates the response of the resonator (e.g., the response of the circuit 500). The first trace 550 illustrates the response of the circuit 500 (or equivalent) in the first mode of operation (corresponding to the first trace 544 of the first graph 540), and the second trace 552 illustrates the response of the circuit 500 in the second mode of operation (corresponding to the second trace 546 of the first graph 540). The third trace 554 illustrates the response of the circuit 500 with the additional tuning switched in (corresponding to the third trace 548 of the first graph 540).

As the graphs illustrates, the responses of other filter and resonator can be shifted to higher or lower frequencies while retaining their general shape.

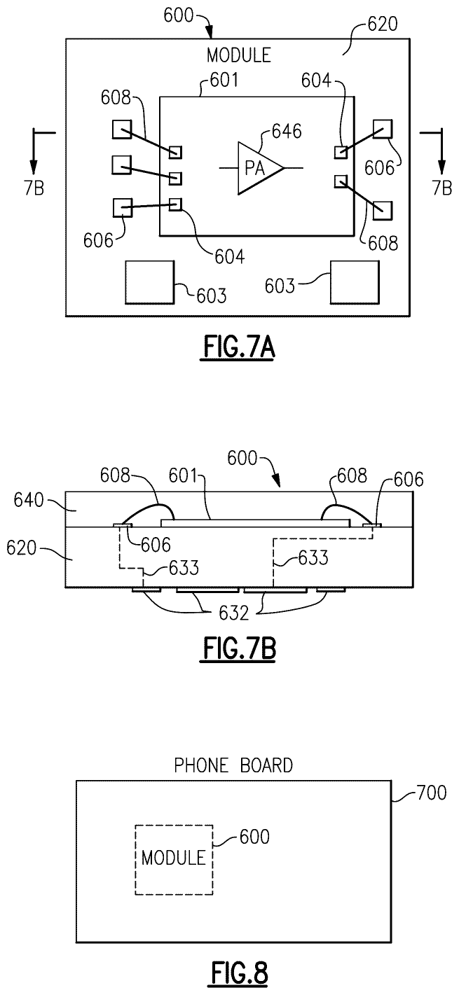

FIG. 7A is a schematic diagram of one embodiment of a packaged module 600. FIG. 7B is a schematic diagram of a cross-section of the packaged module 600 of FIG. 7A taken along the lines 7B-7B.

The packaged module 600 includes an IC or die 601, surface mount components 603, wirebonds 608, a package substrate 620, and encapsulation structure 640. The package substrate 620 includes pads 606 formed from conductors disposed therein. Additionally, the die 601 includes pads 604, and the wirebonds 608 have been used to electrically connect the pads 604 of the die 601 to the pads 606 of the package substrate 620.

The die 601 includes a power amplifier 646, which can be implemented in accordance with any of the embodiments herein.

The packaging substrate 620 can be configured to receive a plurality of components such as the die 601 and the surface mount components 603, which can include, for example, surface mount capacitors and/or inductors.

As shown in FIG. 7B, the packaged module 600 is shown to include a plurality of contact pads 632 disposed on the side of the packaged module 600 opposite the side used to mount the die 601. Configuring the packaged module 600 in this manner can aid in connecting the packaged module 600 to a circuit board such as a phone board of a wireless device. The example contact pads 632 can be configured to provide RF signals, bias signals, power low voltage(s) and/or power high voltage(s) to the die 601 and/or the surface mount components 603. As shown in FIG. 7B, the electrical connections between the contact pads 632 and the die 601 can be facilitated by connections 633 through the package substrate 620. The connections 633 can represent electrical paths formed through the package substrate 620, such as connections associated with vias and conductors of a multilayer laminated package substrate.

In some embodiments, the packaged module 600 can also include one or more packaging structures to, for example, provide protection and/or facilitate handling of the packaged module 600. Such a packaging structure can include overmold or encapsulation structure 640 formed over the packaging substrate 620 and the components and die(s) disposed thereon.

It will be understood that although the packaged module 600 is described in the context of electrical connections based on wirebonds, one or more features of the present disclosure can also be implemented in other packaging configurations, including, for example, flip-chip configurations.

FIG. 8 is a schematic diagram of one embodiment of a phone board 700. The phone board 700 includes the module 600 shown in FIGS. 6A-6B attached thereto. Although not illustrated in FIG. 8 for clarity, the phone board 700 can include additional components and structures.

Some of the embodiments described above have provided examples in connection with wireless devices or mobile phones. However, the principles and advantages of the embodiments can be used for any other systems or apparatus that have needs for power amplifiers.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. An acoustic filter assembly for operating at a first band adjacent to a second band without a spacing between the first band and the second band, the acoustic filter assembly comprising:
a band-pass filter configured to allow signals received via an antenna node to pass at a pass band, the band-pass filter having a transition band between the passband and a stopband; and
an interface configured to receive a control signal that controls a width of the pass band such that the transition band is shifted in frequency, the control signal adjusting a location of the transition band between a first position and a second position, one end of the transition band near to the stopband being aligned with a boundary between the first band and the second band in the first position, the other end of the transition band near to the pass band being aligned with the boundary between the first band and the second band in the second position.

2. The acoustic filter assembly of claim 1 wherein the first band has a lower frequency range than the second band.

3. The acoustic filter assembly of claim 1 wherein the first band is an unlicensed band and the second band is a licensed band.

4. The acoustic filter assembly of claim 1 wherein the control signal is configured to adjust the location of the transition band between the first position and the second position depending on a required amount of traffic in the first band and a required amount of traffic in the second band.

5. The acoustic filter assembly of claim 1 wherein the first band covers a frequency range from 5945 MHz to 6425 MHz.

6. The acoustic filter assembly of claim 1 wherein the boundary between the first band and the second band is located at 6425 MHz.

7. The acoustic filter assembly of claim 1 wherein the band-pass filter includes at least one resonator which is selectively connected with a reactive element by the control signal to adjust a resonance frequency or an anti-resonance frequency of the resonator.

8. The acoustic filter assembly of claim 7 wherein the reactive element is at least one of a capacitor and an inductor.

9. The acoustic filter assembly of claim 1 wherein the band-pass filter is configured such that the location of the transition band is shifted using an RF cancellation that involves adding a phase-inverted signal according to the control signal.

10. A radio frequency module comprising:
a packaging substrate configured to receive a plurality of components;
an acoustic filter assembly for operating at a first band adjacent to a second band without a spacing between the first band and the second band, the acoustic filter assembly implemented on the packaging substrate, the acoustic filter assembly including
a band-pass filter configured to allow signals received via an antenna node to pass at a pass band, the band-pass filter having a transition band between the passband and a stopband, and
an interface configured to receive a control signal that controls a width of the pass band such that the transition band is shifted in frequency, the control signal adjusting a location of the transition band between a first position and a second position, one end of the transition band near to the stopband being aligned with a boundary between the first band and the second band in the first position, the other end of the transition band near to the pass band being aligned with the boundary between the first band and the second band in the second position; and
a controller configured to provide the control signal.

11. The radio frequency module of claim 10 wherein the radio frequency module is a front-end module.

12. The radio frequency module of claim 10 wherein the first band has a lower frequency range than the second band.

13. The radio frequency module of claim 10 wherein the first band is an unlicensed band and the second band is a licensed band.

14. The radio frequency module of claim 10 wherein the control signal is configured to adjust the location of the transition band between the first position and the second position depending on a required amount of traffic in the first band and a required amount of traffic in the second band.

15. The radio frequency module of claim 10 wherein the first band covers a frequency range from 5945 MHz to 6425 MHz.

16. The radio frequency module of claim 10 wherein the boundary between the first band and the second band is located at 6425 MHz.

17. The radio frequency module of claim 10 wherein the band-pass filter includes at least one resonator which is selectively connected with a reactive element by the control signal to adjust a resonance frequency or an anti-resonance frequency of the resonator.

18. The radio frequency module of claim 17 wherein the reactive element is at least one of a capacitor and an inductor.

19. The radio frequency module of claim 10 wherein the band-pass filter is configured such that the location of the transition band is shifted using an RF cancellation that involves adding a phase-inverted signal according to the control signal.

20. A wireless device comprising:
a transceiver configured to generate a radio frequency signal; and
a front end system including an acoustic filter assembly for operating at a first band adjacent to a second band without a spacing between the first band and the second band, the acoustic filter assembly including
a band-pass filter configured to allow signals received via an antenna node to pass at a pass band, the band-pass filter having a transition band between the passband and a stopband, and
an interface configured to receive a control signal that controls a width of the pass band such that the transition band is shifted in frequency, the control signal adjusting a location of the transition band between a first position and a second position, one end of the transition band near to the stopband being aligned with a boundary between the first band and the second band in the first position, the other end of the transition band near to the pass band being aligned with the boundary between the first band and the second band in the second position.
